(19) United States
(12) Patent Application Publication
(10) Pub. No.: US 2008/0095067 A1
(43) Pub. Date: Apr. 24, 2008

(54) APPLICATION MANAGEMENT OBJECTS AND WiMax MANAGEMENT OBJECTS FOR MOBILE DEVICE MANAGEMENT

(76) Inventor: Bindu Rama Rao, Laguna Niguel, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/867,370

(22) Filed: Oct. 4, 2007

Related U.S. Application Data
(60) Provisional application No. 60/850,159, filed on Oct. 5, 2006.

(51) Int. Cl. G01R 31/00

(52) U.S. Cl. 370/252

(57) ABSTRACT

A method and system for interfacing to an electronic device is disclosed. The interfacing may enable the electronic device to communicate with a WiMax network by provisioning parameters for various fields in WiMax management objects. The provisioning may be accomplished by a user of the electronic device, with help of a customer service representative of the WiMax network service provider, and/or information exchange between the servers of the WiMax network and the electronic device. The information exchange between the electronic device and the WiMax servers may occur, for example, per connection, periodically, and/or upon change of information for one or more of said management objects. Information for provisioning the electronic device may also be, for example, communicated via a non-WiMax network.

The present application makes reference to, claims priority to, and claims benefit of U.S. Provisional Application Ser. No. 60/850,159 entitled “Application Management Objects And WiMax Management Objects For Mobile Device Management,” filed Oct. 5, 2006, the complete subject matter of which is hereby incorporated herein by reference, in its entirety.

The Applicant hereby identifies the following patent applications pursuant to 37 C.F.R. §1.78(f)(1):

U.S. patent application Ser. No. 11/839,143 (Attorney Docket No. 200702207-2) filed Aug. 15, 2007;

PCT Application No. PCT/US07/76001 (Attorney Docket No. 200702207-3) filed Aug. 15, 2007;

U.S. patent application Ser. No. 11/847,658 (Attorney Docket No. 200702209-3) filed Aug. 30, 2007;

PCT Application No. PCT/US07/77288 (Attorney Docket No. 200702209-2) filed Aug. 30, 2007;

U.S. patent application Ser. No. 11/854,414 (Attorney Docket No. 200702210-3) filed Sep. 12, 2007; and

PCT Application No. ______ (Attorney Docket No. 200702210-2) filed Sep. 12, 2007.

### BACKGROUND OF THE INVENTION

Electronic devices, such as mobile phones and personal digital assistants (PDA's), often contain firmware and application software that are either provided by the manufacturers of the electronic devices, by telecommunication carriers, or by third parties. When a user starts his subscription with a service provider, various service options may need to be configured for the electronic device in accordance with the user's service plan. Accordingly, various parameters may need to be set or changed in an electronic device before a user is able to use his electronic device properly. However, different electronic devices may have different set of resources, different sets of parameters, etc., and managing the wide variety of mobile devices in a heterogeneous network may be a problem.

Further limitations and disadvantages of conventional and traditional approaches will become apparent to one of skill in the art, through comparison of such systems with the present invention as set forth in the remainder of the present application with reference to the drawings.

### BRIEF DESCRIPTION OF SEVERAL VIEWS OF THE DRAWINGS

FIG. 1 is a perspective block diagram of a network that is capable of provisioning and managing WiMax based electronic devices, in accordance with an embodiment of the present invention.

FIG. 2 is a diagram of an exemplary management object for quality of service classes, in accordance with an embodiment of the present invention.

FIG. 3A is a diagram of an exemplary management object for connectivity parameters, in accordance with an embodiment of the present invention.

FIG. 3B is a diagram of an exemplary management object for connectivity parameters, in accordance with an embodiment of the present invention.

FIG. 4 is a diagram of an exemplary application management object, in accordance with an embodiment of the present invention.

FIG. 5 is a diagram of an exemplary diagnostic management object, in accordance with an embodiment of the present invention.

FIG. 6 is a flowchart of an exemplary method for supporting use of management objects for WiMax, in accordance with an embodiment of the present invention.

### DETAILED DESCRIPTION OF THE INVENTION

Aspects of the present invention relates generally to an interface between an electronic device and a network, and, more specifically, to application management objects and WiMax management objects for mobile device management. While the following discussion focuses primarily on mobile electronic devices such as, for example, a mobile handset, a cellular phone, a personal digital assistant, a pager, and a handheld personal computer, this is by way of example and not by way of specific limitations of the present invention. The teachings contained herein may also be applicable to a variety of other electronic devices for which a device and network capable of mobile device management may be desirable.

Various embodiments of the present invention may comprise interfacing to electronic devices using wired or wireless communication channels such as, for example, a public switched telephone network, a wired local or wide area network, an intranet, the Internet, and wireless cellular, paging, local area, personal area, and various networks such as those referred to as WiFi, WiMax, Bluetooth, and similar types of communication links.

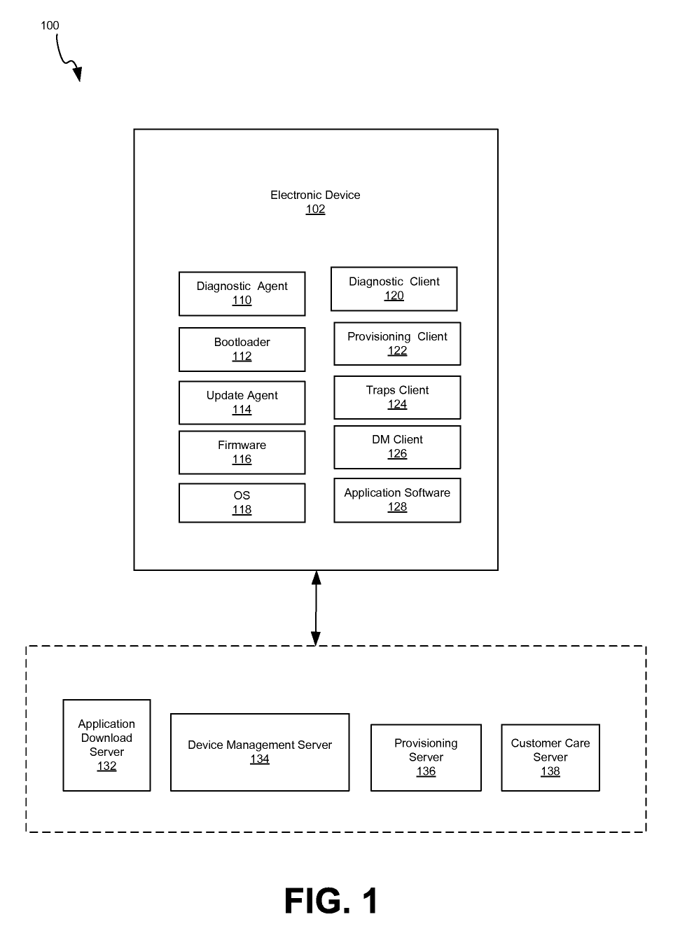

FIG. 1 is a perspective block diagram of a network that is capable of provisioning and managing WiMax based electronic devices, in accordance with an embodiment of the present invention. Referring to FIG. 1, there is shown a network system 100 that comprises a plurality of servers 132 . . . 138, such as, for example, an application download server 132, a device management (DM) server 134, a provisioning server 136, and a customer care server 138. There is also shown an electronic device 102 that may communicate with one or more of the servers 132 . . . 138.

The electronic device 102 may be, for example, a mobile terminal such as a cellular phone or a personal digital assistant (PDA). The electronic device 102 may comprise code that may be resident in various memory devices (not shown). The term “code” may be used herein to represent one or more of executable instructions, operand data, configuration parameters, and other information stored in the electronic device 102.

Some exemplary code that may reside in the electronic device 102 may comprise, for example, a diagnostic agent 110, a bootloader 112, an update agent 114, firmware 116, operating system 118, diagnostic client 120, provisioning client 122, traps client 124, device management client 126, and application software 128.

The diagnostic agent 110 in the electronic device 102 may be a client side diagnostics application that runs on the electronic device 102 when needed and which manages and collects tracing information. The tracing information may be communicated to a server, for example, wirelessly via a data network. The diagnostic agent 110 may also monitor one or more applications, where the monitoring may be constant or periodic. The bootloader 112 may comprise suitable code that may be executed upon power-up, or system reset, to bring the electronic device 102 to an operational state. After the initial booting of the system, for example, the operating system 118 may control operation of the electronic device 102. The update agent 114 may comprise suitable code that may allow, for example, installation and/or updating of the various codes in the electronic device 102. The firmware 116 may comprise, for example, code that may enable specific functionalities of the electronic device 102 to be executed.

The diagnostic client 120 may facilitate remote diagnosis of the electronic device 102. The diagnostic client 120 may also be downloaded and executed to collect diagnostic data from applications, etc. The provisioning client 122 may enable provisioning of the electronic device 102. Provisioning of the electronic device 102 may comprise, for example, providing information to various data structures needed by various functionalities. Some functionalities may comprise, for example, communication via a wireless network, such as a WiMax network, repairing of configuration problems, and/or configuring of software and/or hardware.

The traps client 124 may facilitate the setting of traps and retrieving of collected information. The device management (DM) client 126 may comprise code that may allow interaction with the DM server 134, the diagnostic agent 110, the diagnostic client 120, and the traps client 124, to receive DM commands from the DM server 134 and to implement them in the electronic device 102. The application software 128 may comprise code that may allow a user to access various functionalities. The application download server 132 may be employed to download and/or update applications to the electronic device 102. The application download server 132 may also be used to download new firmware/software such as, for example, the diagnostics client 120, which may then be installed and activated in the electronic device 102.

The DM server 134 may support an Open Mobile Alliance (OMA) DM protocol by which the OMA DM-based application manipulates OMA DM-capable electronic devices such as, for example, the electronic device 102. The electronic device 102 may also receive provisioning information from, for example, the provisioning server 136 that may enable repairing of configuration problems or reconfiguring software and/or hardware. The electronic device 102 may be used to request updates to software/firmware via a customer care server 138 either directly by using a browser application in the electronic device 102, or via a customer service representative (CSR). The CSR may, for example, provide service to the customer using the electronic device 102 by retrieving, as necessary, one or more diagnostic management objects (MOs) that may be stored in memory of the electronic device 102. For example, the CSR may cause update information in the form of one or more update packages to be transmitted to the electronic device 102 from a remote server. Such update packages may, for example, comprise instructions to convert or transform a first version of software/firmware to a second version of software/firmware.

A user of the electronic device 102 may access, for example, a self-care website/portal (not shown) to request customer care service via the customer care server 138, using the device capability information as one of the parameters provided. A customer service representative (CSR) can then provide service to the customer using the electronic device 102, after determining the device capability information that is retrieved from the electronic device 102, thereby making it unnecessary for a customer to provide such information himself to a CSR. The network system 100 is capable of supporting remote diagnostics by a CSR via the customer care server 138. It can also support a diagnostic data collection request from a DM server 134 and return the collected diagnostics data to the DM server 134 or to any other authorized server in the network system 100. The customer/subscriber of the electronic device 102 might be having problems and may need some help in diagnosing the problems—the network system 100 facilitates diagnosis by a CSR via the customer care server 138, as well as by the DM server 134.

An embodiment of the present invention may be used to provision the electronic device 102, which may, for example, comprise WiMax communication capabilities with connectivity parameters that are bearer-specific and bearer-agnostic in the operator network. The term “WiMax” may be used herein to refer to the wireless metropolitan area network communication technology also known as the Institute of Electrical and Electronics Engineers, Inc. (IEEE) 802.16 family of standards. A WiMax management object (WiMax MO) may provide support for provisioning, managing and querying WiMax connectivity information, quality of service (QoS) information, etc. In addition, QoS categories can be supported by the management objects. Applications that correspond to QoS parameter mapping may also be supported.

Also, event logs comprising a single log file, a set of log files, a set of buckets, a set of log segments, etc. may be used for logging events for a plurality of categories where event data may be desired. For example, event logs may be employed to collect information for various device features where diagnosis data collection and/or tracing/debugging may be turned on in the electronic device 102. Event logs may also be used to selectively collect information on specific events that are monitored, such as, for example, device specific data being collected, network performance data, etc.

The event logs may then be retrieved from the electronic device server side in pull or push mode. Traps may refer to other management objects. For example, a Trap MO may provide a reference to one or more event logs, or to one or more interior nodes of an event log or event logs. When the associated trap fires, the corresponding logging of events and related data is conducted. The event logs may be generated, for example, by various pieces of code as they are executed.

The electronic device 102 is capable of receiving update packages from one of the servers 132 . . . 138. The electronic device 102 is capable of applying the received update packages using one or more update agents 114 that are each capable of processing update packages or subsets thereof. The electronic device 102 also comprises the DM client 126 that is capable of interacting with the provisioning client 122, the diagnostic client 120 and the traps client 124. The DM client 126 typically receives DM commands from the DM server 134 and implements them. The application download server 132 is used to download firmware and software updates. It is also used to retrieve a bundle of applications needed to update a minimal or generic electronic device 102 into a device that comprises all applications corresponding to a user's subscription level or service plan.

Provisioning of carrier-specific models of electronic devices is also supported in the network system 100. In addition, a minimal carrier-specific electronic device 102 can be provisioned to work effectively with different services in the network system 100, and also be updated with additional applications subscribed to by a user. The additional applications may be those that the electronic device 102 does not initially provide, and where the user is entitled to use those additional applications according to a user's service plan.

Accordingly, in accordance with an embodiment of the present invention, the network system 100 may provision the electronic device 102 for specific device features or applications. The network system 100 may be capable of supporting management of the electronic device 102. The network system 100 may appropriately personalize the electronic device 102 based on a subscription profile for the electronic device 102, and based on the preferences of the user/subscriber and/or information retrieved from the electronic device 102.

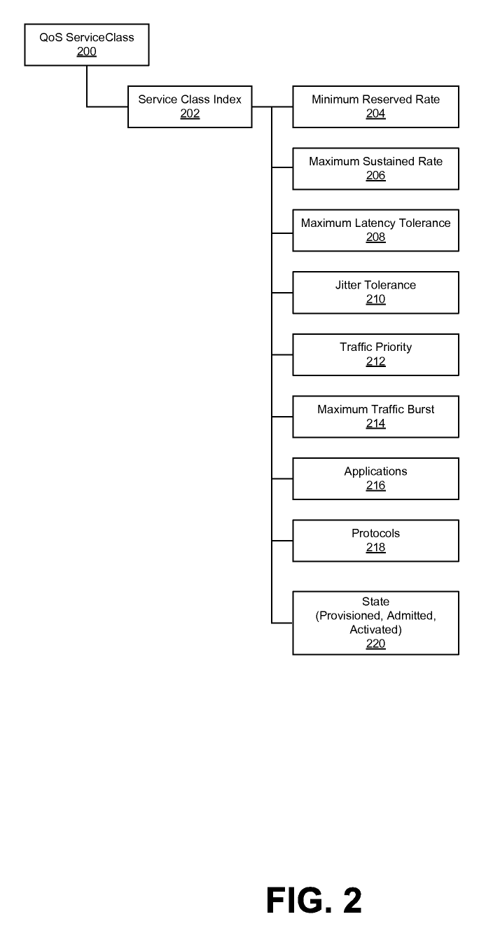

FIG. 2 is a diagram of an exemplary management object for quality of service classes, in accordance with an embodiment of the present invention. Each quality of service profile may contain metrics, which may be as simple as, for example, a maximum and minimum bandwidths, based upon class of service requirements. The class of service requirements may be, for example, whether the service is constant bit rate, committed information rate, or best effort.

Referring to FIG. 2, there is shown a management object for a quality of service (MOQOS) class 200. The MOQOS class 200 may comprise, for example, a service class index field 202, which may comprise a minimum reserved rate field 204, a maximum sustained rate field 206, a maximum latency tolerance field 208, a jitter tolerance field 210, a traffic priority field 212, a maximum traffic burst field 214, an applications field 216, a protocols field 218, and a state of electronic device field 220. These exemplary fields may provide information for QoS for audio streaming, video streaming, voice over Internet protocol (VoIP) calls, video surveillance, internet browsing, and other applications.

For example, a VoIP application may be assigned to an unsolicited grant services class that may use the maximum sustained rate field 206, the maximum latency tolerance field 208, and jitter tolerance field 210. Streaming audio may be assigned to real-time polling service (rtPS) class that may use the minimum reserved rate field 204, the maximum sustained rate field 206, the maximum latency tolerance field 208, the traffic priority field 212, and the maximum traffic burst field 214. VoIP applications that allow voice activity detection may be assigned to an extended rtPS class that may use the minimum reserved rate field 204, the maximum sustained rate field 206, the maximum latency tolerance field 208, the jitter tolerance field 210, and the traffic priority field 212.

Other classes may be, for example, non-real-time polling service (nrtPS), which may comprise the file transfer protocol. The nrtPS may use the minimum reserved rate field 204, the maximum sustained rate field 206, the traffic priority field 212, and the maximum traffic burst field 214. Web browsing may be assigned to the best-effort service class that may use the maximum sustained rate field 206, and the traffic priority field 212.

Other fields, such as, for example, the applications field 216 may indicate the applications that an electronic device may be subscribed to. The protocols field 218 may indicate the protocols that an electronic device may use for communication. The state field 220 may indicate whether the electronic device may be activated or provisioned.

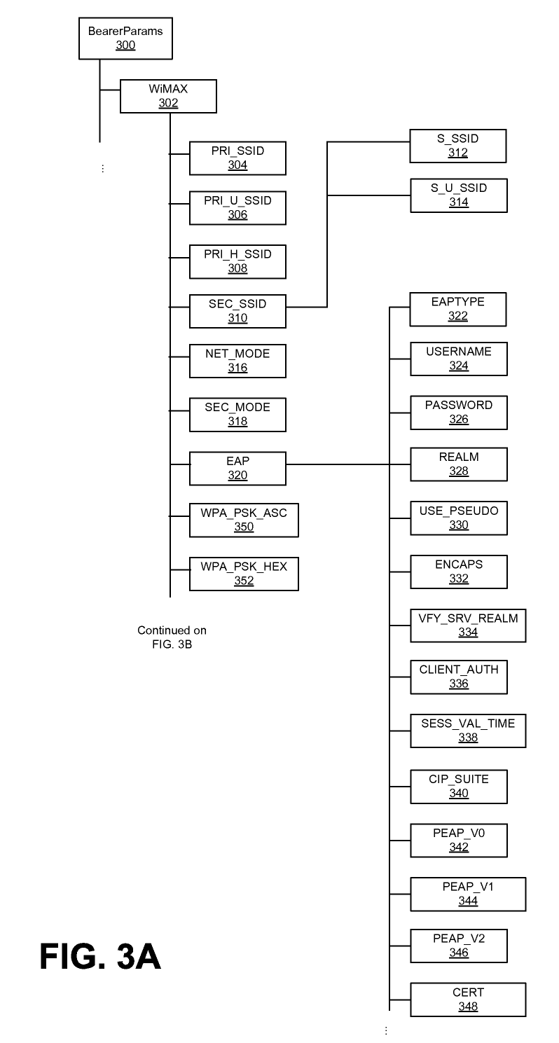

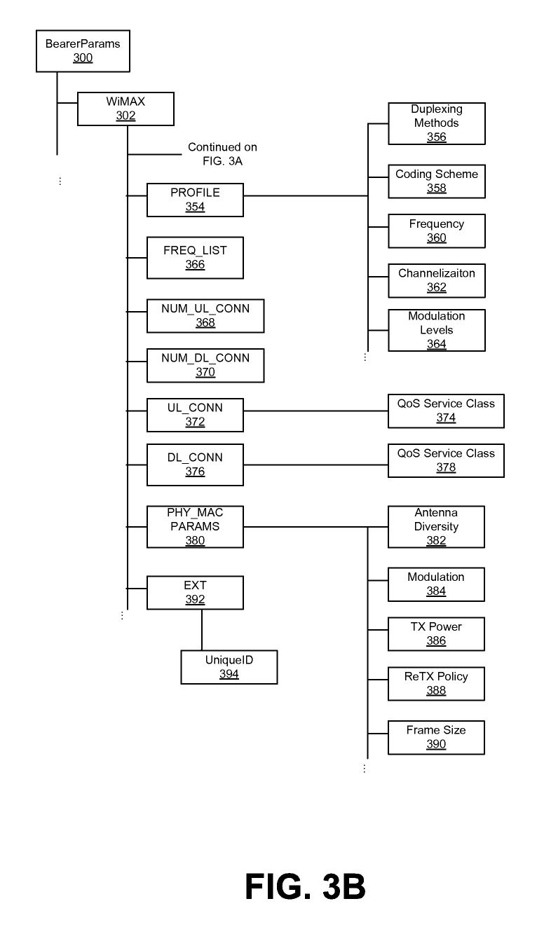

FIG. 3A is a diagram of an exemplary management object for connectivity parameters, in accordance with an embodiment of the present invention. Referring to FIG. 3A, there is shown a bearer parameters field 300, which may comprise an exemplary WiMax management object 302. The WiMax management object 302 may comprise, for example, a PRI_SSID field 304, a PRI_U_SSID field 306, a PRI_H_SSID field 308, a SEC_SSID field 310, a NET_MODE field 316, a SEC_MODE field 318, an EAP field 320, a WPA-PSK-ASC field 350, and a WPA-PSK-DEC field 352.

The PRI_SSID field 304 may be, for example, for a network name shared by a plurality of wireless devices on a WiMax network. The PRI_U_SSID field 306 may be, for example, a used primary network name. The PRI_H_SSID field 308 may indicate, for example, that a SSID is hidden. The SEC_SSID field 310 may point to, for example, fields S_SSID 312 and S_U_SSID 314. The S_SSID field 312 may be, for example, a secondary SSID. The S_U_SSID 314 field may be, for example, a used secondary network name.

The NET_MODE field 316 may indicate, for example, a mode of operation for a WiMax network. The SEC_MODE field 318 may indicate, for example, a security mode for a WiMax network. The EAP field 320 may point to, for example, a EAP_TYPE field 322, a USERNAME field 324, a PASSWORD field 326, a REALM field 328, a USER_PSEUDO field 330, a ENCAPS field 332, a VFY_SRV_REALM field 334, a CLIENT_AUTH field 336, a SESS_VAL_TIME field 338, a CIP_SUITE 340, a PEAP_V0 field 342, a PEAP_V1 field 344, a PEAP_V2 field 346, and a CERT field 348.

The EAP_TYPE field 322 may specify, for example, which of the various extensible authentication protocol (EAP) methods that are supported by WiMax may be used in this particular network. The USERNAME field 324 may specify, for example, a user's identity. The PASSWORD field 326 may comprise a password used for EAP authentication. The REALM field 328 may indicate an override realm in the EAP response packet. The USER_PSEUDO field 330 may indicate that pseudonyms are used. The ENCAPS field 332 may indicate the encapsulating EAP type for which the this parameter is associated. For example, if the ENCAPS field 332 indicates “EAP-PEAP,” then the settings may be meant for EAP-PEAP encapsulation.

The VFY_SRV_REALM field 334 may indicate, for example, whether a realm of the server's certificate is checked. The CLIENT_AUTH field 336 may indicate, for example, that a server perform client authentication. The SESS_VAL_TIME field 338 may indicate, for example, how many minutes an authentication session may be valid. The CIP_SUITE 340 may indicate allowed cipher suites. The PEAP_V0 field 342, the PEAP_V1 field 344, and the PEAP_V2 field 346 may indicate which of the PEAP versions may be used. The CERT field 348 may indicate a type of certificate used by a user. The WPA_PSK_ASC field 350 and the WPA_PSK_DEC field 352 may be used to store, for example, a security key in ASCII and decimal format, respectively.

FIG. 3B is a diagram of an exemplary management object for connectivity parameters, in accordance with an embodiment of the present invention. Referring to FIG. 3B, there is shown additional exemplary fields for the WiMax management object 302. The WiMax management object 302 may comprise, for example, a PROFILE field 354, a FREQ_LIST field 366, a NUM_UL_CONN field 368, a NUM_DL_CONN field 370, a UL_CONN field 372, a DL_CONN field 376, a PHY_MAC field 380, and an EXT field 392.

The Profile field 354 may point to, for example, a Duplexing methods field 356, a Coding_Scheme field 358, a Frequency field 360, a Channelization field 362, and a Modulation_Level field 364, among others. The FREQ_LIST field 366 may comprise, for example, a list of frequencies that may be used by the network. The NUM_UL_CONN field 368 and the NUM_DL_CONN field 370 may indicate, for example, the number of up-link connections and the number of down-link connections, respectively. The UL_CONN field 372 may point to, for example, a QoS Service Class MO 374 that may specify parameters for up-link communication. Similarly, the DL_CONN field 376 may point to, for example, a QoS Service Class MO 378 that may specify parameters for down-link communication.

The PHY_MAC_Params field 380 may point to various parameters that may be used for Phy layer or MAC layer protocol. For example, the PHY_MAC_Params field 308 may point to an Antenna_Diversity field 382, a Modulation field 384, a TX_power field 386, a ReTx_Policy field 388, and a Frame_Size field 390. The Antenna_Diversity field 382 may indicate, for example, whether antenna diversity may be used. The Modulation field 384 may indicate a type of modulation used, such as, for example, binary phase shift keyed (BPSK), quadrature phase shifted keyed (QPSK), quadrature amplitude modulation—16 points (QAM16), and quadrature amplitude modulation—64 points (QAM 64). The EXT field 392 may point to, for example, a UniqueID field 394, among others, where the UniqueID field 394 may comprise an ID that may be generated for server control.

It should be noted that a representative embodiment of the present invention, such as those illustrated in FIG. 3A and FIG. 3B, may comprise a management object that may be referred to as a bearer (e.g., WiMax) device details (e.g., “devdetails”) management object and/or a management object that may be referred to as bearer (e.g., WiMax) device information (e.g., “devinfo”) management object. Such device details and device information management objects may comprise a collection of certain ones or subsets of those elements of the WiMax MO 302 shown in FIG. 3A and FIG. 3B, for example.

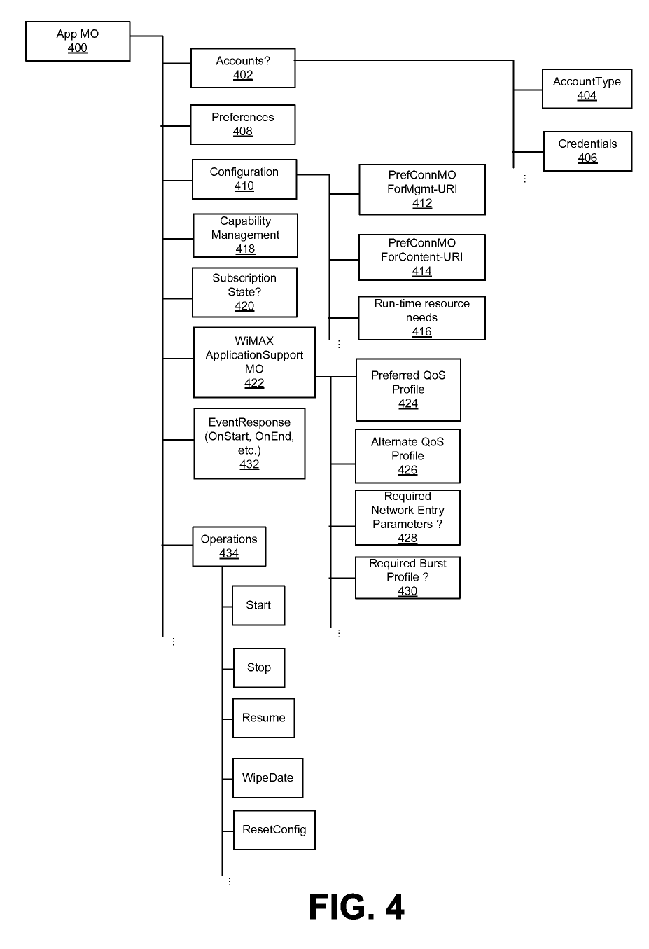

FIG. 4 is a diagram of an exemplary application management object, in accordance with an embodiment of the present invention. Referring to FIG. 4, there is shown exemplary fields for the application management object 400 that may comprise information regarding accounts with service providers and networks, preferred connectivity management objects for management commands and content delivery, run-time resource configuration, event responses, WiMax bearer specific quality of service needs, and a set of operations that may be invoked.

The application management object 400 may comprise, for example, an Accounts field 402, a Preferences field 408, a Configuration field 410, a Capabilities Management field 418, a Subscription State field 420, a WiMax Application Support field 422, an Event Response field 432, and an Operations field 434. The Accounts field 402 may point to, for example, an Account Type field 404 and a Credentials field 406. The Account Type filed 404 may indicate, for example, whether the account is a billed monthly or a pay-as-you-go type account. The Credentials field 406 may comprise, for example, information for verifying the user to a service provider. The Preferences field 408 may indicate, for example, previously selected preferences for a present application.

The Configuration field 410 may comprise, for example, a PrefConnMOforMgmt field 412, PrefConnMOforContent field 414, and run-time resource need field 416. The PrefConnMOforMgmt field 412 may point to a management object that may comprise parameters for a preferred connection. The preferred connection MO may comprise, for example, information that may allow the electronic device 102 to be managed by the servers 132 . . . 138. This may include, for example, updating various code in the electronic device 102, performing diagnostics, etc.

The PrefConnMOforContent field 414 may point to a management object that may comprise parameters for content. For example, content MO may comprise information that may indicate preferences for music, type of news, hobbies, etc. Accordingly, the information in the content MO may be used in conjunction with, for example, the quality of service parameters. The run time resource need field 416 may specify, for example, various resources needed when a particular application is running. This may comprise, for example, amount of free memory needed. The run time resource need field 416 may also verify, for example, versions that may be supported by the electronic device 102 and/or code in the electronic device 102.

The Capability management field 418 may comprise, for example, parameters that may indicate capability limitations for an application. For example, the maximum bandwidth allowed for uplink and/or downlink may be part of the Capability management field 418. The subscription state field 420 may indicate, for example, whether a user is subscribed to an application.

The WiMax Applications Support MO field 422 may point to a MO that may comprise, for example, a Preferred QoS Profile field 424, an alternate QoS Profile field 426, a Required Network Entry Parameters field 428, and a Required Burst Profile field 430. The Preferred QoS Profile field 424 and the alternate QoS Profile field 426 may comprise, for example, QoS Service Class management objects that may be similar to the MOQOS class 200 for indicating a quality of service desired. The parameters saved in the Preferred QoS Profile field 424 and the alternate QoS Profile field 426 may indicate, for example, maximum and minimum bandwidth based on class of service requirements. The class of service requirements may comprise, for example, constant bit rate service, committed information rate service, and/or best effort service.

The Required Network Entry Parameters field 428 may comprise information that may be used by an application for making connections on a network. The Required Burst Profile field 430 may comprise, for example, information that may be used to indicate supported packet bursts on a network. The Operations field 434 may comprise, for example, various states such as Start, Stop, Resume, and/or ResetConfig. Selecting ResetConfig may, for example, use default values for specific parameters in the Application MO 400.

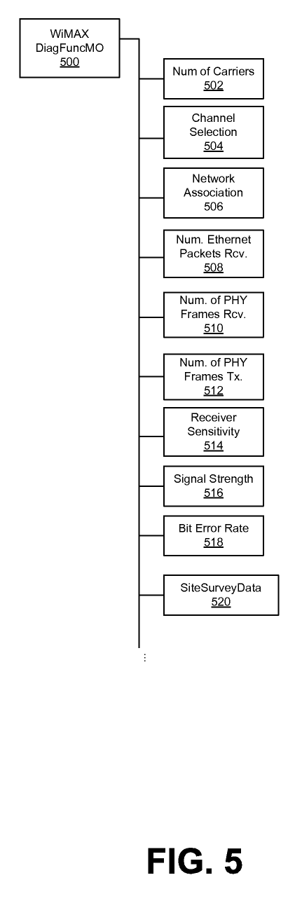

FIG. 5 is a diagram of an exemplary diagnostic management object, in accordance with an embodiment of the present invention. Referring to FIG. 5, there is shown exemplary fields for the diagnostics management object 500 that may be used to diagnose performance of the WiMax network currently used by the electronic device 102. The diagnostics MO 500 may comprise among others, for example, a Number of Carriers field 502, a Channel Selection field 504, a Network Association field 506, a Number of Ethernet Packets Received field 508, a Number of PHY Frames Received field 510, a Number of PHY Frames Transmitted field 512, Receiver Sensitivity field 514, Signal Strength field 516, Bit Error Rate field 518, and SiteSurveyData field 520.

The Number of Carriers field 502 may indicate, for example, a number of carriers that may be detected in the current network. The Channel Selection field 504 may indicate, for example, determining whether a selected channel may be accessed by the electronic device 102. The Network Association field 506 may indicate whether the electronic device 102 may be able to join a specified network. The Number of Ethernet Packets Received field 508 may indicate a number of Ethernet packets received as a result of running diagnostics.

The Number of PHY Frames Received field 510 and the Number of PHY Frames Transmitted field 512 may indicate network throughput. The Receiver Sensitivity field 514 may indicate, for example, a lowest signal strength for which the electronic device 102 may reliably receive data. The Signal Strength field 516 may indicate, for example, signal strength during this diagnostic routine. The Bit Error Rate field 518 may indicate the number of bit errors received during this diagnostic routine. The SiteSurveyData field 520 may indicate a summary of the various results of the diagnostics run on the electronic device 102.

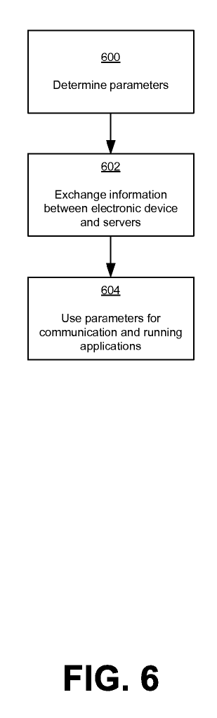

FIG. 6 is a flowchart of an exemplary method for supporting use of management objects for WiMax, in accordance with an embodiment of the present invention. Referring to FIG. 6, there is shown steps 600 to 604. In step 600, a user of the electronic device 102, which may be a mobile device that may be purchased by a user, for example, may enter values into the various management objects described with respect to FIGS. 2-5. Some of the parameters may be provisioned during activation of the electronic device 102, and others may be changed as new applications are enabled. The electronic device 102 may also have some parameters pre-provisioned to default values, or provided in a subscriber identity module (SIM).

Some of the parameters populated may be, for example, for the QoS fields 204 . . . 220, for the WiMax fields 304 . . . 390, for the application fields 402 . . . 430, and/or the WiMax diagnostics fields 502 . . . 520. Some fields may be populated by the user, and others may be populated by code in the electronic device 102, while still others may be populated via information from the servers 132 . . . 138. For example, the user may enter one or more pieces of information for the security related EAP fields 322 . . . 346

Various embodiments of the present invention may also allow a user to access a self-care web-site (not shown) for activation and/or enabling of new applications. Accordingly, the electronic device 102 may be pre-provisioned for accessing a self-care web-site, or the provisioning may be available via a SIM. Some service providers may, for example, enable a customer service representative to download this information via another wireless connection, such as, for example, a cellular data connection. Various embodiments of the present invention may also enable information stored in the servers 132 . . . 138 to be downloaded to the electronic device 102. For example, some of this information may be those related to the bearer fields 356 . . . 364 and/or 382 . . . 390.

Various embodiments of the present invention may also enable information in the parameter fields in the electronic device 102 to be communicated to one or more of the servers 132 . . . 138. Some of this information may comprise, for example, the diagnostics information 502 . . . 520 and portions of the QoS profiles 424 and 426.

In step 602, the electronic device 102 may communicate with one or more of the servers 132 . . . 138. Part of the communication may be to, for example, update and/or exchange information from the electronic device 102 to the servers 132 . . . 138, and/or from the servers 132 . . . 138 to the electronic device 102. Some of the information may be new because the user of the electronic device 132 . . . 138 may have just subscribed to an application, or the user may have changed subscription level. For example, the user may have increased his download link speed, and accordingly, various QoS parameters may be changed.

In step 604, the electronic device 102 may communicate via a WiMax network using the parameters stored in the electronic device 102 and/or the servers 132 . . . 138. For example, the user may have subscribed to a voice over IP (VoIP) service using WiMax networks. Accordingly, after the electronic device 102 is provisioned for the various parameters of the management objects described with respect to FIGS. 2-5 for the VoIP service, the user may now be able to make and/or receive VoIP calls.

Although a system and method according to the present invention has been described in connection with the preferred embodiment, it is not intended to be limited to the specific form set forth herein, but on the contrary, it is intended to cover such alternative, modifications, and equivalents, as can be reasonably included within the scope of the present invention as defined by this disclosure and appended diagrams.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for interfacing to an electronic device, the method comprising: storing information in one or more management objects for use with a wireless network compatible with one of the Institute of Electrical and Electronics Engineers, Inc. (IEEE) 802.16 family of standards, wherein said information is used for functionality that comprises one or more of: activation, diagnostics, subscription to services, and quality of service selections.

2. The method according to claim 1, wherein said one or more management objects comprise one or more of: quality of service management object, WiMax bearer parameter management object, application management object, and diagnostics management object.

3. The method according to claim 1, comprising provisioning said one or more management objects in the electronic device by a user of the electronic device.

4. The method according to claim 1, comprising provisioning said one or more management objects in the electronic device via a customer service representative of said IEEE 802.16 compatible wireless network service provider.

5. The method according to claim 1, comprising provisioning said one or more management objects in the electronic device via servers of said wireless network service provider.

6. The method according to claim 1, comprising provisioning said one or more management objects in the electronic device via a wireless network other than said IEEE 802.16 compatible wireless network.

7. The method according to claim 1, comprising communicating said information in said one or more management objects between the electronic device and servers of said IEEE 802.16 compatible wireless network at one or more of the following events: per connection, periodically, and/or upon change of information for one or more of said management objects.

8. A machine-readable storage having stored thereon, a computer program having at least one code section for interfacing to an electronic device, the at least one code section being executable by a machine for causing the machine to perform steps comprising: storing information in various management objects for use with a wireless network compatible with one of the Institute of Electrical and Electronics Engineers, Inc. (IEEE) 802.16 family of standards, wherein said information is used for functionality that comprises one or more of: activation, diagnostics, subscription to services, and quality of service selections.

9. The machine-readable storage according to claim 8, wherein said management objects comprise one or more of: a quality of service management object, a WiMax bearer parameter management object comprising one or both of a WiMax device details management object and a WiMax device information management object, an application management object, and a diagnostics management object.

10. The machine-readable storage according to claim 8, wherein the at least one code section comprises code that enables provisioning of said management objects in the electronic device by a user of the electronic device.

11. The machine-readable storage according to claim 8, wherein the at least one code section comprises code that enables provisioning of said management objects in the electronic device via a customer service representative of said IEEE 802.16 compatible wireless network service provider.

12. The machine-readable storage according to claim 8, wherein the at least one code section comprises code that enables provisioning of said management objects in the electronic device via servers of said wireless network service provider.

13. The machine-readable storage according to claim 8, wherein the at least one code section comprises code that enables provisioning of said management objects in the electronic device via a wireless network other than said IEEE 802.16 compatible wireless network.

14. The machine-readable storage according to claim 8, wherein the at least one code section comprises code that enables communication of said information in said management objects between the electronic device and servers of said IEEE 802.16 compatible wireless network at one or more of the following events: per connection, periodically, and/or upon change of information for one or more of said management objects.

15. A system for interfacing to an electronic device, the system comprising: one or more processors that enable storing of information in various management objects for use with a wireless network compatible with one of the Institute of Electrical and Electronics Engineers, Inc. (IEEE) 802.16 family of standards, wherein said information is used for functionality that comprises one or more of: activation, diagnostics, subscription to services, and quality of service selections.

16. The system according to claim 15, wherein said one or more processors enable provisioning of said management objects in the electronic device by a user of the electronic device.

17. The system according to claim 15, wherein said one or more processors enable provisioning of said management objects in the electronic device via a customer service representative of said IEEE 802.16 compatible wireless network service provider.

18. The system according to claim 15, wherein said one or more processors enable provisioning of said management objects in the electronic device via servers of said wireless network service provider.

19. The system according to claim 15, wherein said one or more processors enable provisioning of said management objects in the electronic device via a wireless network other than said IEEE 802.16 compatible wireless network.

20. The system according to claim 15, wherein said one or more processors enable communication of said information in said management objects between the electronic device and servers of said IEEE 802.16 compatible wireless network at one or more of the following events: per connection, periodically, and/or upon change of information for one or more of said management objects.
